(19) United States
(12) Patent Application Publication
(10) Pub. No.: US 2026/0157222 A1
(43) Pub. Date: Jun. 4, 2026

(54) METHODS OF PACKAGING TRANSISTOR

(71) Applicant: OIP Technology Pte Ltd, Singapore (SG)

(72) Inventors: Guoxiong WU, Singapore (SG); Xilin XIA, Singapore (SG); Saifeng HUANG, Singapore (SG); ZhengYu Branden HOE, Singapore (SG)

(21) Appl. No.: 19/019,697

(22) Filed: Jan. 14, 2025

(30) Foreign Application Priority Data
Nov. 29, 2024 (CN) 202411744870.X

(51) Int. Cl. H01L 23/00; H01L 21/56; H01L 23/31; H01L 23/498; H10D 80/20

(52) U.S. Cl. CPC H10W 74/019; H10D 80/251; H10W 70/09; H10W 70/60; H10W 70/6528; H10W 70/658; H10W 72/874; H10W 74/10; H10W 74/121; H10W 90/00; H10W 90/734

(57) ABSTRACT

The present invention provides a method of packaging a transistor, which includes: bonding a chip having a front side with collector, emitter and ground terminals of the transistor formed thereon and a backside with a base terminal of transistor formed on, at the backside, to a carrier substrate; forming a first metal layer on a surface of carrier substrate using an RDL process and forming a second metal layer on front side of chip using RDL process, which is connected to each of collector, emitter and ground terminals; forming a first mold resin layer, and removing carrier substrate; polishing the first mold resin layer; forming a third metal layer using an RDL process; forming a second mold resin layer; cutting away portions of the first and second mold resin layers, exposing side faces of the first metal layer; and connecting both the first metal layer and base terminal to surface of a lead frame.

### CROSS-REFERENCES TO RELATED APPLICATION

This application claims the priority of Chinese patent application number 202411744870.X, filed on Nov. 29, 2024, the entire contents of which are incorporated herein by reference.

### TECHNICAL FIELD

The present invention relates to the field of integrated circuit (IC) packaging, and particularly to methods of packaging a transistor.

### BACKGROUND

A transistor may be packaged to make it stable and easy to deploy.

In conventional transistor packaging, a wire bonding process is used to establish connections with a circuit. This may particularly include providing a lead frame 110 and attaching a transistor chip 120 to the lead frame 110. Collector, emitter, based and ground terminals of the transistor chip 120 may be bonded by bonding wires 130 to four pins on the lead frame. After that, a mold resin layer 140 may be formed to encapsulate the transistor chip 120 on the lead frame 110.

However, due to limitations of such wire bonding techniques, the conventional transistor packaging is associated with the disadvantages as follows: 1) a large package size; 2) overheating of the bonding wires when large currents flow therethrough due to their significant parasitic inductance and capacitance; and 3) poor electrical contact due to loose or broken connections.

### SUMMARY

It is an objective of the present invention to provide methods of packaging a transistor, which enable a reduced package size and prevent overheating and poor electrical contact.

To this end, the present invention provides a method of packaging a transistor, which includes:
providing a carrier substrate and a chip, the chip having a front side and an opposite backside, the chip including collector, emitter and ground terminals of the transistor on the front side, the chip including a base terminal of the transistor on the backside, and bonding the backside of the chip to the carrier substrate;
forming a first metal layer on a surface of the carrier substrate using a redistribution layer (RDL) process and forming a second metal layer on the front side of the chip using an RDL process, which is connected to each of the collector, emitter and ground terminals;
forming a first mold resin layer, which encapsulates the chip and the first and second metal layers, and removing the carrier substrate;
polishing away partial thicknesses of the first mold resin layer, exposing surfaces of the first and second metal layers;
forming a third metal layer using an RDL process, which connects the first metal layer to the second metal layer;
forming a second mold resin layer, which encapsulates the third metal layer and covers the first mold resin layer and the first and second metal layers;
cutting away portions of the first and second mold resin layers, exposing side faces of the first metal layer; and
providing a lead frame and connecting both the first metal layer and the base terminal to a surface of the lead frame.

Optionally, in the method, the first, second and third metal layers may each have a thickness greater than 50 μm.

Optionally, in the method, the lead frame may include a plurality of pins.

Optionally, in the method, the lead frame may include solder balls on the surface, through which the first metal layer and the collector terminal are connected to the surface of the lead frame.

Optionally, in the method, the backside of the chip may be bonded to the carrier substrate using a bonding adhesive.

The present invention provides another method of packaging a transistor, which includes:
providing a carrier substrate and a chip, the chip having a front side and an opposing backside, the chip including collector, emitter and ground terminals of the transistor on the front side, the chip including a base terminal of the transistor on the backside, and bonding the front side of the chip to the carrier substrate;
forming a first metal layer on a surface of the carrier substrate using an RDL process and forming a second metal layer on the backside of the chip using an RDL process, which is connected to the base terminal;
forming a first mold resin layer, which encapsulates the chip and the first and second metal layers, and removing the carrier substrate;
polishing away partial thicknesses of the first mold resin layer, exposing surfaces of the first and second metal layers;
forming a third metal layer using an RDL process, which connects the first metal layer to the second metal layer;
forming a fourth metal layer on the front side of the chip using an RDL process, which is connected to each of the collector, emitter and ground terminals and also to the first metal layer;
forming a second mold resin layer, which encapsulates the third and fourth metal layers and covers the first mold resin layer and the first and second metal layers;
cutting away portions of the first and second mold resin layers, exposing side faces of the first metal layer; and
providing a lead frame and connecting both the first and fourth metal layers to a surface of the lead frame.

Optionally, in the method, the first, second, third and fourth metal layers may each have a thickness greater than 50 μm.

Optionally, in the method, the lead frame may include a plurality of pins.

Optionally, in the method, the lead frame may include solder balls on the surface, through which the first and fourth metal layers are connected to the surface of the lead frame.

Optionally, in the method, the backside of the chip may be bonded to the carrier substrate using a bonding adhesive.

In the methods proposed herein, RDL processes are employed to form first, second and third metal layers, and optionally a fourth metal layer, which connect the components of the chip to the lead frame. Compared with convention methods adopting wire bonding, the present invention enables a reduced package size and prevents overheating and poor electrical contact.

### BRIEF DESCRIPTION OF THE DRAWINGS

FIG. 1 schematically illustrates a conventional transistor packaging process.

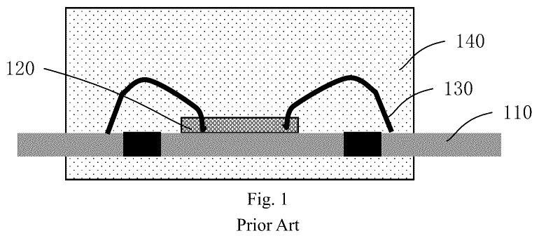

FIG. 2 is a flowchart of a method of packaging a transistor according to a first embodiment of the present invention.

FIGS. 3, 4, 7 to 9 and 11 to 12 are schematic longitudinal cross-sectional views of structures resulting from steps in the method according to the first embodiment.

FIGS. 5, 6 and 10 are top views of structures resulting from steps in the method according to the first embodiment.

FIG. 13 is a flowchart of a method of packaging a transistor according to a second embodiment of the present invention.

FIGS. 14 to 19 are schematic longitudinal cross-sectional views of structures resulting from steps in the method according to the second embodiment.

In the figures, 110 denotes a lead frame; 120, a transistor chip; 130, a wire; 140, a mold resin encapsulation layer; 210, a carrier substrate; 220, a chip; 230, a bonding adhesive; 240, a first metal layer; 250, a second metal layer; 260, a first mold resin layer; 270, a third metal layer; 280, a second mold resin layer; 290, a lead frame; 310, a carrier substrate; 320, a chip; 330, a bonding adhesive; 340, a first metal layer; 350, a second metal layer; 360, a first mold resin layer; 370, a third metal layer; 380, a fourth metal layer; 390, a second mold resin layer; and 400, a lead frame.

### DETAILED DESCRIPTION

The present invention will be described in greater detail below with reference to the accompanying drawings, which illustrate specific embodiments thereof. From the following description, advantages and features of the present invention will be more apparent. Note that the figure is provided in a very simplified form not necessarily drawn to exact scale for the only purpose of helping to explain the disclosed embodiments in a more convenient and clearer way.

As used hereinafter, the terms “first”, “second” and the like may be used to distinguish between similar elements without necessarily implying any particular ordinal or chronological sequence. It will be understood that the terms so used are interchangeable, whenever appropriate. Likewise, if a method is described herein as including a series of steps, the order of these steps as presented herein is not necessarily the only order in which they can be performed, and certain ones of the stated steps may be possibly omitted and/or certain other steps not described herein may be possibly added to the method.

It will be understood that when a layer (or film), region, pattern or structure is referred to as being “above” a substrate, other layer (or film), region and/or pattern, it may be directly on the other layer or substrate, or intervening layer(s) may also be present. It will also be understood that when a layer is referred to as being “under” another layer, it may be directly under or below the other layer, or one or more intervening layers may also be present. Further, reference to a layer being “above” or “under” another layer is made herein based on the orientation of the accompanying drawings.

### Example 1

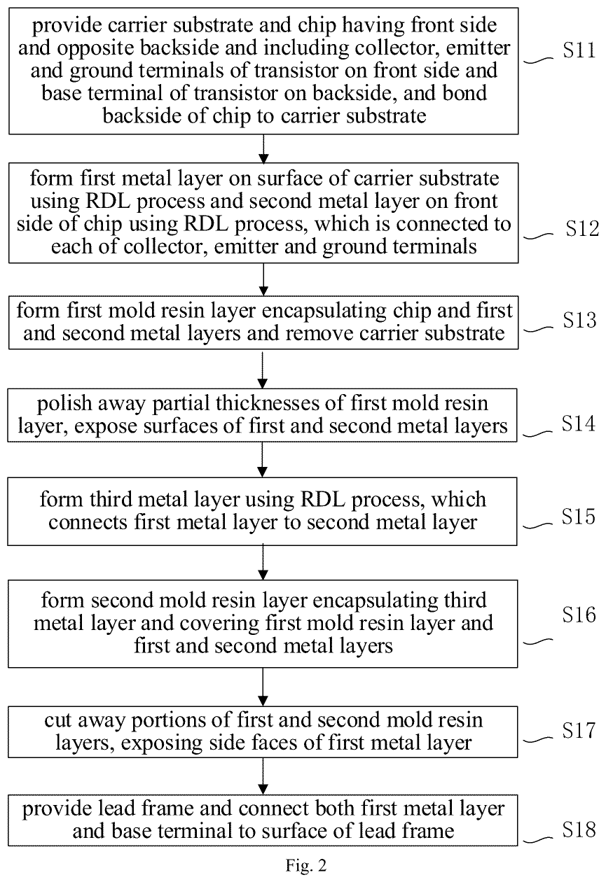

Referring to FIG. 2, in a first embodiment of the present invention, there is provided a method of packaging a transistor, which includes:
S11) providing a carrier substrate and a chip, the chip having a front side and a backside, the chip including collector, emitter and ground terminals of the transistor on the front side of the chip, the chip including a base terminal of the transistor on the backside of the chip, and bonding the backside of the chip to the carrier substrate;
S12) forming a first metal layer on a surface of the carrier substrate using a redistribution layer (RDL) process and forming a second metal layer on the front side of the chip using an RDL process, which is connected to each of the collector, emitter and ground terminals;
S13) forming a first mold resin layer, which encapsulates the chip and the first and second metal layers, and removing the carrier substrate;
S14) polishing away partial thicknesses of the first mold resin layer, exposing surfaces of the first and second metal layers;
S15) forming a third metal layer using an RDL process, which connects the first metal layer to the second metal layer;
S16) forming a second mold resin layer, which encapsulates the third metal layer and covers the first mold resin layer and the first and second metal layers;
S17) cutting away portions of the first and second mold resin layers, exposing side faces of the first metal layer; and
S18) providing a lead frame and connecting both the first metal layer and the base terminal to a surface of the lead frame.

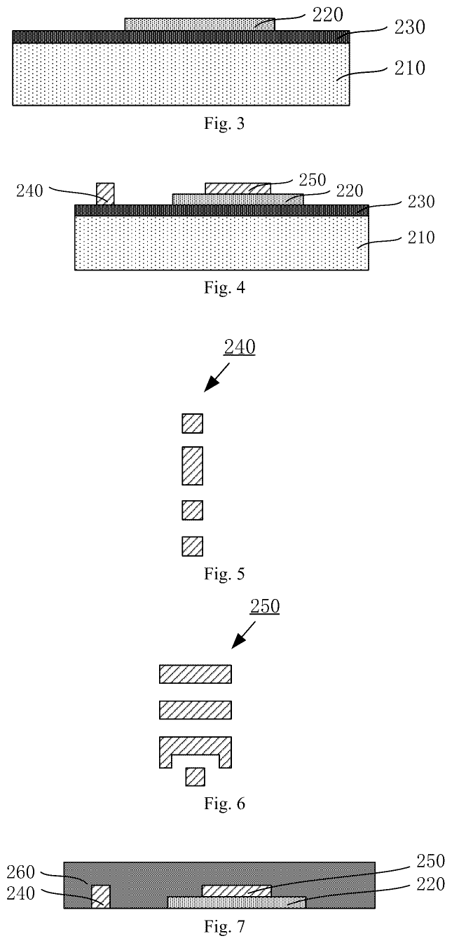

Referring to FIG. 3, at the beginning, a carrier substrate 210 and a chip 220 are provided. The chip 220 has a front side and an opposite backside. Collector, emitter and ground terminals of the transistor are on the front side of the chip 220, and a base terminal of the transistor is on the backside of the chip 220. The backside of the chip 220 is then bonded to the carrier substrate 210 with a bonding adhesive 230 so that the chip 220 covers a surface portion of the carrier substrate 210.

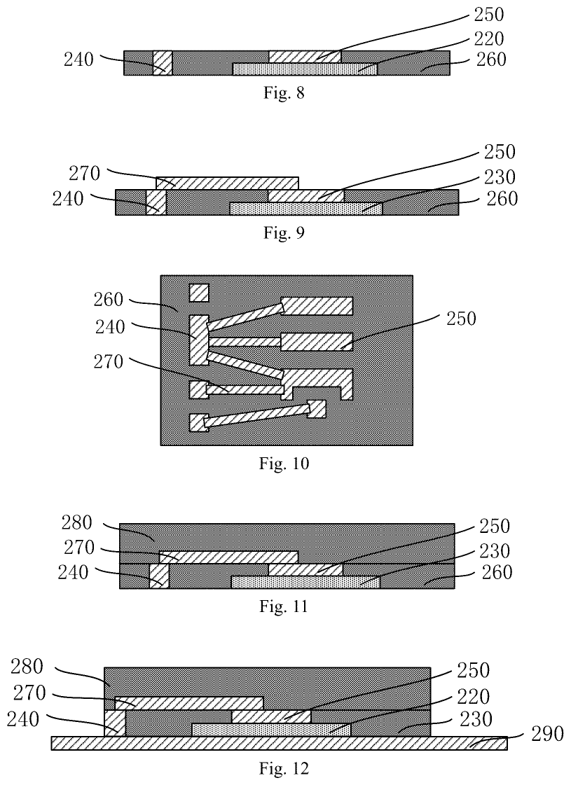

Next, referring to FIG. 4, a first metal layer 240 is formed on the surface of the carrier substrate 210 not covered by the chip 220 using an RDL process. Moreover, a second metal layer 250 is formed on the front side of the chip 220 using an RDL process. The first metal layer 240 is spaced apart from the chip 220. The layout of the first metal layer 240 is shown in FIG. 5. The second metal layer 250 is connected to each of the collector, emitter and ground terminals, and the layout of the second metal layer 250 is shown in FIG. 6.

Subsequently, referring to FIG. 7, a first mold resin layer 260 is formed, which encapsulates the chip 220, the first metal layer 240 and the second metal layer 250, followed by removal of the carrier substrate 210 and the bonding adhesive 230.

Afterwards, referring to FIG. 8, partial thicknesses of the first mold resin layer 260 are polished away, exposing surfaces of the first metal layer 240 and the second metal layer 250.

Reference is then made to FIGS. 9 to 10. FIG. 10 is a top view corresponding to FIG. 9. A third metal layer 270 is formed using an RDL process, which connects the first metal layer 240 to the second metal layer 250. The third metal layer 270, the first metal layer 240 and the second metal layer 250 each have a thickness greater than 50 μm.

Next, referring to FIG. 11, a second mold resin layer 280 is formed, which encapsulates the third metal layer 270 and covers the first mold resin layer 260, the first metal layer 240 and the second metal layer 250.

Subsequently, referring to FIG. 12, undesired portions of the first mold resin layer 260 and the second mold resin layer 280 are cut away, exposing side faces of the first metal layer 240. A lead frame 290 is then provided, and the first metal layer 240 and the base terminal on the backside of the chip 220 are both connected to a surface of the lead frame 290. In particular, the lead frame 290 may have solder balls on the surface, through which the first metal layer 240 and the collector terminal may be connected to the surface of the lead frame 290. Thus, the lead frame 290 is connected by the first metal layer 240, the third metal layer 270 and the second metal layer 250 to the components on the front side of the chip 220, such as the collector, emitter and ground terminals. The lead frame 290 may be a metal frame having multiple pins. In this way, the chip 220 is packaged so that the functional terminals of the transistor can be connected to an external circuit via the pins on the lead frame 290.

### Example 2

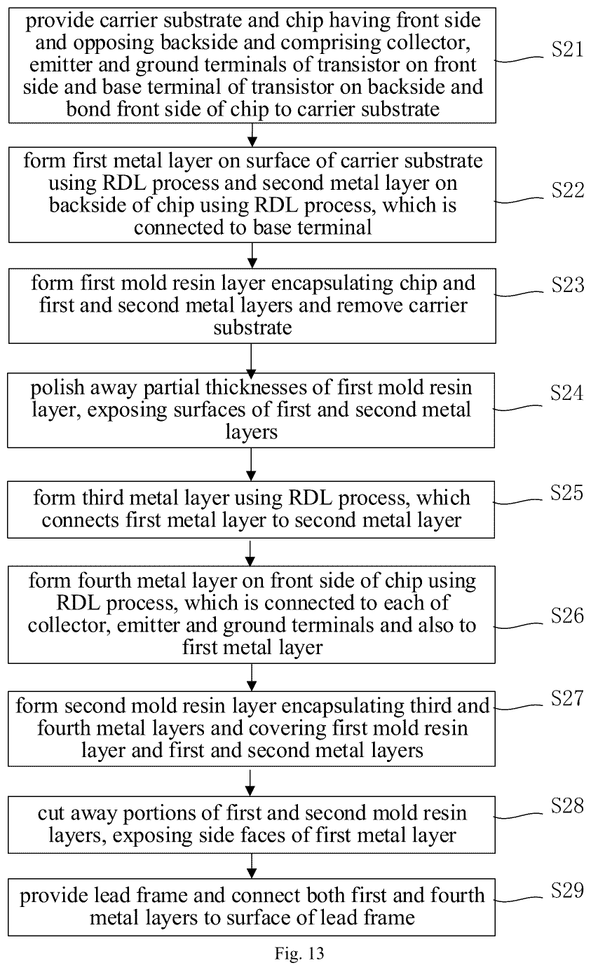

Referring to FIG. 13, in a second embodiment of the present invention, there is provided a method of packaging a transistor, which includes:
S21) providing a carrier substrate and a chip, the chip having a front side and an opposing backside, the chip including collector, emitter and ground terminals of the transistor on the front side of the chip, the chip including a base terminal of the transistor on the backside of the chip, and bonding the front side of the chip to the carrier substrate;
S22) forming a first metal layer on a surface of the carrier substrate using an RDL process and forming a second metal layer on the backside of the chip using an RDL process, which is connected to the base terminal;
S23) forming a first mold resin layer, which encapsulates the chip and the first and second metal layers, and removing the carrier substrate;
S24) polishing away partial thicknesses of the first mold resin layer, exposing surfaces of the first and second metal layers;
S25) forming a third metal layer using an RDL process, which connects the first metal layer to the second metal layer;
S26) forming a fourth metal layer on the front side of the chip using an RDL process, which is connected to each of the collector, emitter and ground terminals and also to the first metal layer;
S27) forming a second mold resin layer, which encapsulates the third and fourth metal layers and covers the first mold resin layer and the first and second metal layers;
S28) cutting away portions of the first and second mold resin layers, exposing side faces of the first metal layer; and
S29) providing a lead frame and connecting both the first and fourth metal layers to a surface of the lead frame.

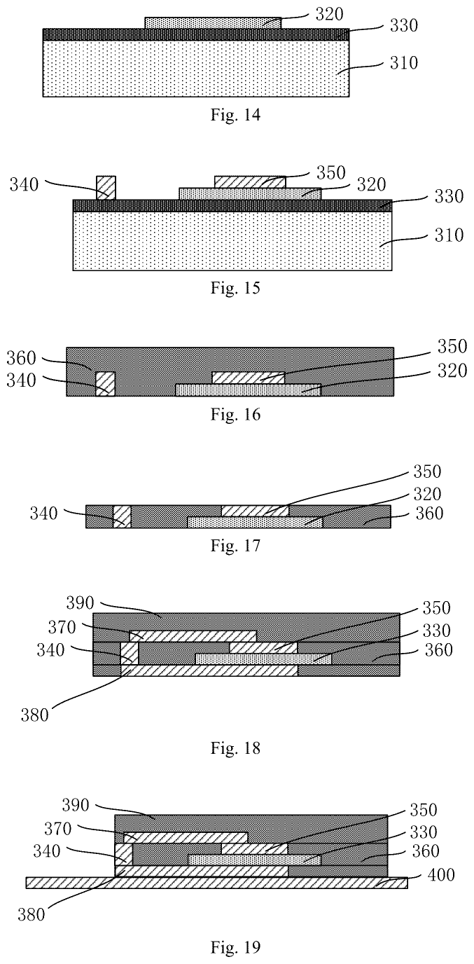

Initially, referring to FIG. 14, a carrier substrate 310 and a chip 320 are provided. The chip 320 has a front side and an opposite backside. Collector, emitter and ground terminals of the transistor are on the front side of the chip 320, and a ground terminal of the transistor is on the backside of the chip 320. The front side of the chip 320 is then bonded to the carrier substrate 310 with a bonding adhesive 330 so that the chip 320 covers a surface portion of the carrier substrate 310.

Next, referring to FIG. 15, a first metal layer 340 is formed on the surface of the carrier substrate 310 using an RDL process, and a second metal layer 350 on the backside of the chip 320 using an RDL process. The second metal layer 350 is connected to the base terminal on the backside of the chip 320, and the first metal layer 340 is spaced apart from the chip 320.

Subsequently, referring to FIG. 16, a first mold resin layer 360 is formed, which encapsulates the chip 320, the carrier substrate 310, the first metal layer 340 and the second metal layer 350, followed by removal of the carrier substrate 310 and the bonding adhesive 330.

Afterwards, referring to FIG. 17, partial thicknesses of the first mold resin layer 360 are polished away, exposing surfaces of the first metal layer 340 and the second metal layer 350. A third metal layer 370 is then formed using an RDL process, which connects the first metal layer 340 to the second metal layer 350.

After that, referring to FIG. 18, a fourth metal layer 380 is formed on the front side of the chip 320, which is connected to the first metal layer 340. The first metal layer 340, the second metal layer 350, the third metal layer 370 and the fourth metal layer 380 each have a thickness greater than 50 μm. A second mold resin layer 390 is then formed, which encapsulates the third metal layer 370 and the fourth metal layer 380 and covers the first mold resin layer 360, the first metal layer 340 and the second metal layer 350.

Next, referring to FIG. 19, undesired portions of the first mold resin layer 360 and the second mold resin layer 390 are cut away, exposing side faces of the first metal layer 340. A lead frame 400 is then provided, and the fourth metal layer 380 is connected to a surface of the lead frame 400. In particular, the lead frame 400 may have solder balls on the surface, through which the fourth metal layer 380 may be connected to the surface of the lead frame 400. Thus, the lead frame 400 is connected by the fourth metal layer 380 to the components on the front side of the chip 220, such as the collector, emitter and ground terminals, and by the first metal layer 340, the third metal layer 370 and the second metal layer 350 to the components on the backside of the chip 320, such as the base terminal. The lead frame 400 may be a metal frame having multiple pins. In this way, the chip 320 is packaged so that the functional terminals of the transistor can be connected to an external circuit via the pins on the lead frame 400.

In summary, in the methods in the above embodiments of the present invention, RDL processes are employed to form first, second and third metal layers, and optionally a fourth metal layer, which connect the components of the chip to the lead frame. Compared with convention methods adopting wire bonding, the present invention enables a reduced package size and prevents overheating and poor electrical contact.

Presented above are merely a few preferred embodiments of the present invention, which do not limit the invention in any way. Changes in any forms made to the principles and teachings disclosed herein, including equivalents and modifications, by any person of ordinary skill in the art without departing from the scope of the invention are intended to fall within the scope of the invention.

1. A method of packaging a transistor, comprising:
providing a carrier substrate and a chip, the chip having a front side and a backside opposite to the front side, the chip comprising collector, emitter and ground terminals of the transistor on the front side, the chip comprising a base terminal of the transistor on the backside, and bonding the backside of the chip to the carrier substrate;
forming a first metal layer on a surface of the carrier substrate using a redistribution layer (RDL) process and forming a second metal layer on the front side of the chip using the RDL process, the second metal layer being connected to each of the collector, emitter and ground terminals;
forming a first mold resin layer, which encapsulates the chip and the first and second metal layers, and removing the carrier substrate;
polishing away partial thicknesses of the first mold resin layer, exposing surfaces of the first second metal layer and the second metal layer;
forming a third metal layer using the RDL process, which connects the first metal layer to the second metal layer;
forming a second mold resin layer, which encapsulates the third metal layer and covers the first mold resin layer, the first metal layer and the second metal layer;
cutting away portions of the first mold resin layer and the second mold resin layer, exposing side faces of the first metal layer; and
providing a lead frame and connecting both the first metal layer and the base terminal to a surface of the lead frame.

2. The method of claim 1, wherein the first metal layer, the second metal layer and the third metal layer each have a thickness greater than 50 μm.

3. The method of claim 1, wherein the lead frame comprises a plurality of pins.

4. The method of claim 1, wherein the surface of the lead frame comprises solder balls, the first metal layer and the collector terminal are connected to the surface of the lead frame through the solder balls.

5. The method of claim 1, wherein the backside of the chip is bonded to the carrier substrate using a bonding adhesive.

6. A method of packaging a transistor, comprising:
providing a carrier substrate and a chip, the chip having a front side and a backside opposite to the front side, the chip comprising collector, emitter and ground terminals of the transistor on the front side, the chip comprising a base terminal of the transistor on the backside, and bonding the front side of the chip to the carrier substrate;
forming a first metal layer on a surface of the carrier substrate using an RDL process and forming a second metal layer on the backside of the chip using the RDL process, the second metal layer being connected to the base terminal;
forming a first mold resin layer, which encapsulates the chip and the first and second metal layers, and removing the carrier substrate;
polishing away partial thicknesses of the first mold resin layer, exposing surfaces of the first metal layer and the second metal layer;
forming a third metal layer using the RDL process, which connects the first metal layer to the second metal layer;
forming a fourth metal layer on the front side of the chip using the RDL process, which is connected to each of the collector, emitter and ground terminals and also to the first metal layer;
forming a second mold resin layer, which encapsulates the third metal layer and the fourth metal layer and covers the first mold resin layer, the first metal layer and the second metal layer;
cutting away portions of the first mold resin layer and the second mold resin layer, exposing side faces of the first metal layer; and
providing a lead frame and connecting both the first metal layer and the fourth metal layer to a surface of the lead frame.

7. The method of claim 6, wherein the first metal layer, the second metal layer, the third metal layer and the fourth metal layer each have a thickness greater than 50 μm.

8. The method of claim 6, wherein the lead frame comprises a plurality of pins.

9. The method of claim 6, wherein the surface of the lead frame comprises solder balls, the first metal layer and the fourth metal layer are connected to the surface of the lead frame through the solder balls.

10. The method of claim 6, wherein the backside of the chip is bonded to the carrier substrate using a bonding adhesive.
